(19) United States
(12) Patent Application Publication
(10) Pub. No.: US 2005/0034674 A1
(43) Pub. Date: Feb. 17, 2005

(54) Processing apparatus for object to be processed and processing method using same

(75) Inventor: Katsuhiko Ono, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/940,779

(22) Filed: Sep. 15, 2004

Related U.S. Application Data
(63) Continuation of application No. PCT/JP03/03648, filed on Mar. 25, 2003.

(30) Foreign Application Priority Data
Mar. 29, 2002 (JP) 2002-094092

(51) Int. Cl. C23C 16/00

(52) U.S. Cl. 118/728

(57) ABSTRACT

A processing apparatus includes a processing vessel; a susceptor installed in the processing vessel and having an electrostatic chuck for attracting and holding an object to be processed; lifter pins, elevatably installed with respect to the susceptor, for separating the object from the susceptor; and a jump-up detection device for detecting whether or not the object jumps up from the susceptor when the object is lifted up to be separated therefrom by the lifter pins, wherein the jump-up detection device has a discharge detection unit for detecting at least one of a discharge current and a discharge voltage generated between the object and the susceptor when the object is separated from the susceptor; and a judging unit for judging whether or not the object jumps up based on a detection result of the discharge detection unit.

This application is a Continuation Application of PCT International Application No. PCT/JP03/03648 filed on Mar. 25, 2003, which designated the United States.

### FIELD OF THE INVENTION

The present invention relates to a processing apparatus for an object to be processed and a processing method, which are capable of automatically detecting whether or not a semiconductor wafer jumps up when the semiconductor wafer is separated from a susceptor in a processing apparatus for a semiconductor wafer or the like using an electrostatic chuck.

### BACKGROUND OF THE INVENTION

Generally, a processing apparatus such as a plasma etching apparatus, a plasma CVD apparatus, a plasma sputtering apparatus or the like includes a susceptor for mounting thereon a semiconductor wafer and a thin electrostatic chuck installed on the susceptor, wherein the semiconductor wafer is actually mounted on a surface of the electrostatic chuck. Further, a DC positive high voltage is continuously applied to the electrostatic chuck during the processing, and a Coulomb force generated therefrom attracts and holds the semiconductor wafer on the susceptor, thereby preventing a misalignment, e.g., a sideway slide of the wafer.

Furthermore, in case a processed semiconductor wafer is unloaded after a predetermined process is completed, even though a positive high voltage stops being applied to the electrostatic chuck, residual charges are present on the semiconductor wafer. Accordingly, if the wafer is separated from the susceptor in such a state, the wafer jumps up strongly. Thus, the wafer itself is damaged by an impact, or particles are generated due to a collision between the wafer and an upper electrode. To that end, a voltage of an opposite polarity with respect to that applied during the processing procedure, herein, a negative high voltage is applied as a charge neutralization voltage to the electrostatic chuck for a few seconds to remove the residual charges. Thereafter, the semiconductor wafer is lifted up from the susceptor by a lifter pin and then unloaded from a processing apparatus to an outside thereof by a transfer arm.

At this time, a value of the negative DC charge neutralization voltage is important. For example, if the charge neutralization voltage is too high, a charge neutralization of the wafer is sufficiently performed and, thus, there is no jump-up of the wafer, whereas it may cause an dielectric breakdown of various fine devices formed on the semiconductor wafer due to a large electric field. On the contrary, if the charge neutralization voltage is too low, the dielectric breakdown of the devices does not occur, whereas the wafer jumps up due to the insufficient charge neutralization whenever it is lifted up to be separated from the susceptor.

Therefore, in a conventional case for obtaining conditions for an optimal charge neutralization voltage, an observation window is installed on a sidewall of a processing vessel, and different charge neutralization voltages are applied to the electrostatic chuck. Further, whenever a different charge neutralization voltage is applied thereto, an interior of the processing vessel is checked with eyes through the observation window to judge whether or not the wafer jumps up.

However, in the aforementioned eye observation, it is difficult to objectively judge an occurrence of the jump-up of the wafer due to individual variances and, thus, a same examination should be iteratively performed to obtain objectivity.

Further, since a state of the occurrence of the jump-up is different depending on, e.g., types of films formed on a wafer surface or there exist differences between individual processing apparatuses, a considerable time is required to search for an optimal charge neutralization voltage for every processing apparatus by judging whether or not the wafer jumps up or obtain conditions for the optimal charge neutralization voltage.

### SUMMARY OF THE INVENTION

It is, therefore, an object of the present invention to provide a processing apparatus for an object to be processed and a processing method.

In accordance with one aspect of the invention, there is provided a processing apparatus including: a processing vessel; a susceptor installed in the processing vessel and having an electrostatic chuck for attracting and holding an object to be processed; lifter pins, elevatably installed with respect to the susceptor, for separating the object from the susceptor; and a jump-up detection device for detecting whether or not the object jumps up from the susceptor when the object is lifted up to be separated therefrom by the lifter pins, wherein the jump-up detection device has a discharge detection unit for detecting at least one of a discharge current and a discharge voltage generated between the object and the susceptor when the object is separated from the susceptor; and a judging unit for judging whether or not the object jumps up based on a detection result of the discharge detection unit.

In accordance with another aspect of the invention, there is provided a processing method for use with a processing apparatus having a processing vessel, a susceptor installed in the processing vessel and including an electrostatic chuck, and lifter pins, the processing method including the steps of: (a) attracting and holding an object to be processed on the susceptor in the processing vessel by a Coulomb force of the electrostatic chuck; (b) separating the object from the susceptor by lifting it up by the lifter pins after applying a charge neutralization voltage to the electrostatic chuck; and (c) detecting whether or not the object jumps up from the susceptor when the object is lifted up by the lifter pins, wherein the detecting step (c) further has the steps of: (c1) detecting at least one of a discharge current and a discharge voltage generated between the object and the susceptor when the object is separated from the susceptor; and (c2) judging whether or not the object jumps up based on a detection result of the step (c1).

### BRIEF DESCRIPTION OF THE DRAWINGS

The above and other objects and features of the present invention will become apparent from the following description of preferred embodiments, given in conjunction with the accompanying drawings, in which:

FIG. 1 shows a processing apparatus for an object to be processed, which processes a semiconductor wafer;

FIG. 2 illustrates a fragmentary enlarged view for explaining a discharge status generated when a semiconductor wafer is lifted up to be separated from the susceptor;

FIG. 3 describes a flowchart for explaining a jump-up detection method of the present invention;

FIG. 4 depicts a relationship between a charge neutralization voltage and an occurrence of a discharge;

FIG. 5A provides an exemplary modification of a connection type of a discharge detection section;

FIG. 5B presents another exemplary modification of a connection type of a discharge detection section; and

FIG. 6 represents a state in which a jump-up detection mechanism for an object to be processed is installed in a plasma etching apparatus.

### DETAILED DESCRIPTION OF THE PREFERRED EMBODIMENTS

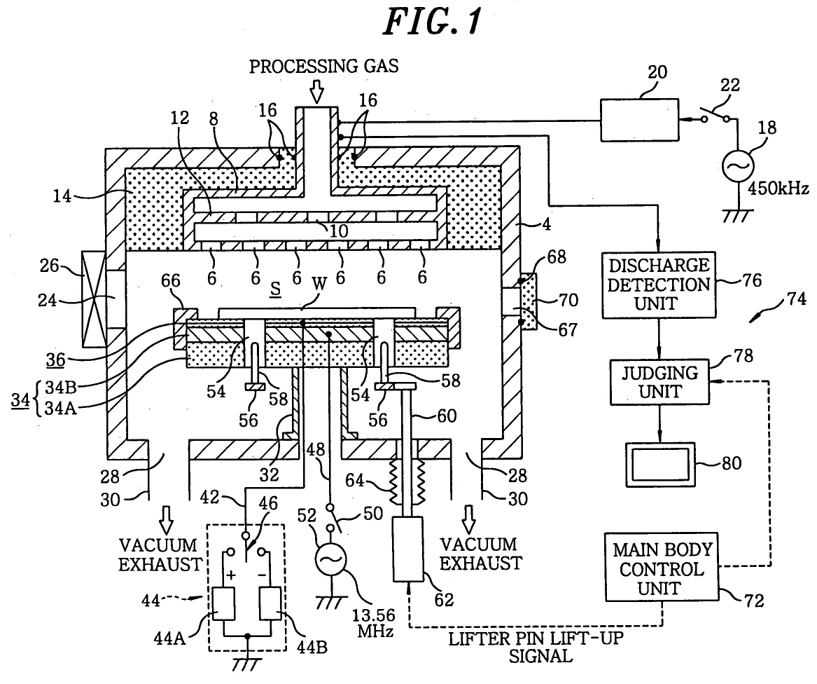

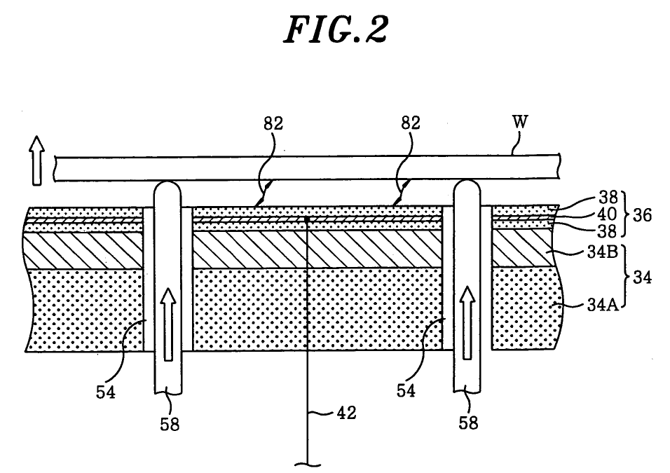

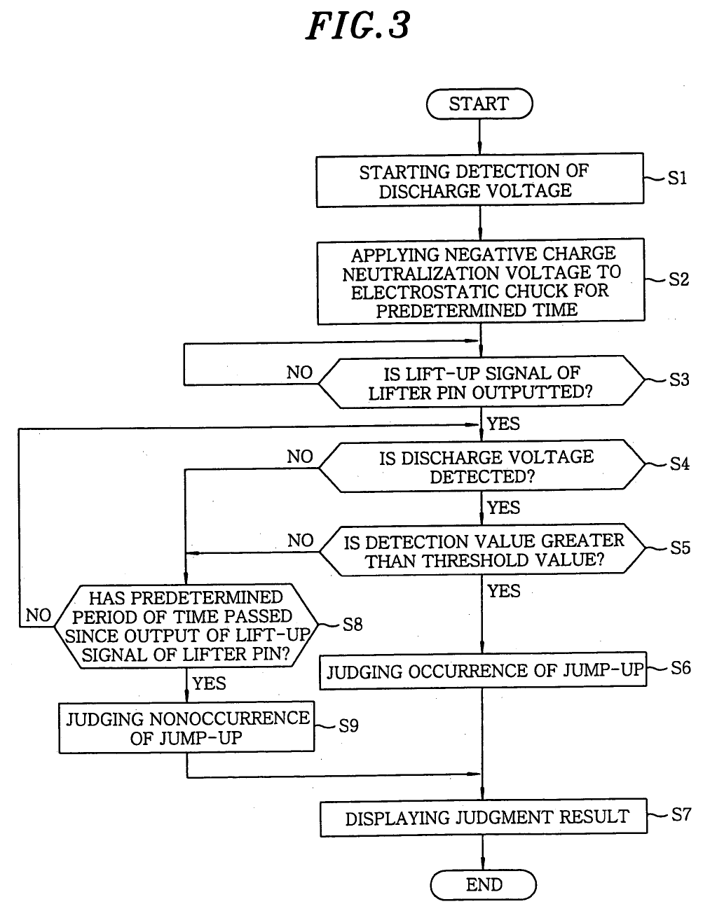

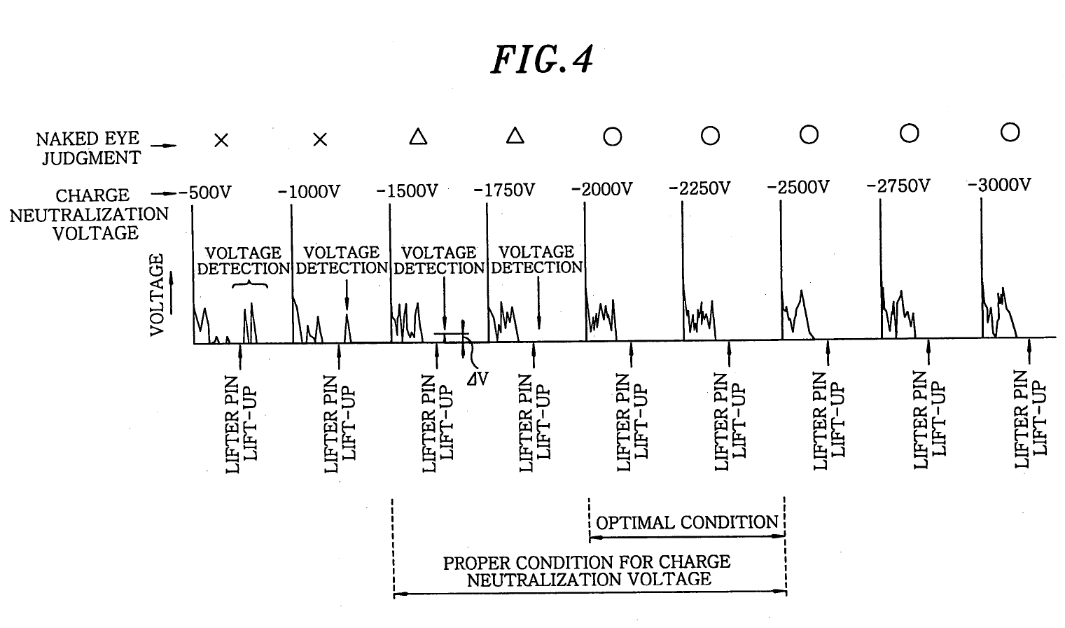

Hereinafter, a processing apparatus for an object to be processed and a processing method in accordance with the present invention will be described. FIG. 1 shows a processing apparatus for an object to be processed, which processes a semiconductor wafer; FIG. 2 illustrates a fragmentary enlarged view for explaining a discharge status generated when a semiconductor wafer is lifted up to be separated from the susceptor; FIG. 3 describes a flowchart for explaining a jump-up detection method of the present invention; and FIG. 4 depicts a relationship between a charge neutralization voltage and an occurrence of a discharge.

Above all, an exemplary processing apparatus for an object to be processed (e.g. wafer) in accordance with the present invention will be described.

As illustrated, a processing apparatus 2 includes a cylindrical processing vessel 4 made of, e.g., nickel or nickel alloys; and a susceptor 34 installed in the processing vessel 4, for mounting thereon a semiconductor wafer W. Installed on a ceiling portion of the processing vessel 4 is a showerhead 8 having on a lower surface thereof a plurality of gas jetting holes 6, so that, e.g., a film forming gas, as a processing gas, can be introduced into a processing space S in the processing vessel 4. The showerhead 8 is horizontally divided into two spaces by a diffusion plate 12 having diffusion holes 10.

The entire showerhead 8 is made of a conductor, e.g., nickel or nickel alloys, and serves as an upper electrode. An outer circumferential portion and an upper portion of the showerhead 8 serving as the upper electrode are entirely covered with an insulator 14 made of, e.g., quartz, alumina (Al₂O₃) or the like. The showerhead 8 is fixedly attached to the processing vessel 4 via the insulator 14 in an insulated state. In this case, sealing members 16 such as an O-ring or the like are interposed between abutments of the showerhead 8, the insulator 14 and the processing vessel 4, thereby maintaining airtightness of the processing vessel 4.

A high frequency power supply 18 for generating a high frequency voltage of, e.g., 450 kHz, and for producing a plasma is connected to the showerhead 8 via a matching circuit 20 and an opening/closing switch 22 and applies, if necessary, a high frequency voltage to the showerhead 8 serving as the upper electrode. Further, a frequency of the high frequency voltage can be, e.g., 13.56 MHz or the like, other than 450 kHz.

Moreover, installed on a sidewall of the processing vessel 4 is a loading/unloading port 24 for loading/unloading the semiconductor wafer w thereinto/therefrom. A gate valve 26, which can be opened and closed, is installed at the loading/unloading port 24 and a load-lock chamber or a transfer chamber that is not shown is connected to the gate valve 26.

Further, a gas exhaust port 28 is provided at a bottom portion of the processing vessel 4, and a gas exhaust line 30 having a vacuum pump or the like, which is not shown, is connected to the gas exhaust port 28 to evacuate an inside of the processing vessel 4, if necessary. Furthermore, as described above, installed in the processing vessel 4 is the susceptor 34 standing on a bottom portion thereof via a support 32, for mounting thereon the semiconductor wafer W. The susceptor 34 serves as a lower electrode, and a plasma can be produced by the high frequency voltage in the processing space S between the showerhead 8 serving as the upper electrode and the susceptor 34 serving as the lower electrode. Specifically, the susceptor 34 includes a ceramic base 34A made of ceramic such as AlN or the like; and a conductor base 34B made of, e.g., aluminum, the conductor base 34B being installed on the ceramic base 34A. Further, a thin electrostatic chuck 36 is installed on the conductor base 34B to be in contact therewith, and the wafer W is directly mounted on the electrostatic chuck 36 to be attracted and held thereon by the Coulomb force.

As shown in FIG. 2, the electrostatic chuck 36 is configured in such a way that a conductor pattern 40 is buried between insulating plates 38 made of, e.g., a ceramic material, a polyimide resin or the like. The conductor pattern 40 is connected to a high voltage DC power supply 44 via, e.g., a lead line 42, so that a DC high voltage can be applied thereto if necessary.

The high voltage DC power supply 44 has a positive DC power supply 44A for generating the Coulomb force that attracts and holds the wafer to the conductor pattern 40; and a negative DC power supply 44B for supplying a charge neutralization voltage having an opposite polarity of the positive DC power supply 44A, wherein both power supplies 44A and 44B can be selectively connected to the conductor pattern 40 by a changeover switch 46. Further, polarities of the power supplies 44A and 44B can be set to be opposite, or a positive voltage and a negative voltage can be selectively applied to the conductor pattern 40 by a switch device (not shown) with a single power supply. In this case, a power supply voltage is variable, and a voltage applied to attract and hold the wafer can be different from that in applying a charge neutralization voltage. Furthermore, with a microcurrent flowing on the insulating plates 38, the wafer W can be attracted and held by using the Johnson-Rahbek force for generating an electric adsorptive force between the insulating plates 38 and the wafer W.

In addition, a high frequency bias power supply 52 of, e.g., 13.56 MHz, is connected to the conductor base 34B of the susceptor 34 via the lead line 48 and the opening/closing switch 50 and applies a bias voltage to the susceptor 34 in processing the wafer. Further, the susceptor 34 can be provided with a temperature controlling heater or a temperature controlling cooling jacket.

Moreover, formed at the susceptor 34 are pin holes 54 vertically penetrating therethrough. Each of lifter pins 58 made of, e.g., quartz, is movably inserted into corresponding one of the pin holes 54, wherein lower portions of the lifter pins 58 are connected to connection rings 56. One of the connection rings 56 is connected to an upper portion of a vertically movable elevation rod 60 penetrating a vessel bottom portion, and an air cylinder 62 is connected to a lower portion of the elevation rod 60. Accordingly, each of the lifter pins 58 is upwardly protruded from a corresponding upper portion of the pin holes 54 when the wafer W is transferred. Further, an expansible/contractible bellows 64 is installed at a portion where the elevation rod 60 penetrates the vessel bottom portion, and the elevation rod 60 can vertically move while maintaining airtightness in the processing vessel 4. Furthermore, a focus ring 66 for collecting a plasma in the processing space S is installed around a peripheral portion of the susceptor 34 serving as the lower electrode. Besides, an observation opening 67 is formed at the sidewall of the processing vessel 4, and an observation window 70 made of, e.g., quartz, is air-tightly attached to the observation opening 67 by sealing members 68 such as an O-ring or the like. Additionally, an entire operation of the processing apparatus 2 is controlled by a main body control section 72 including, e.g., a microcomputer or the like.

A jump-up detection device 74 for a wafer is attached to the processing apparatus 2 to obtain, e.g., conditions for a charge neutralization voltage. Further, in an actual apparatus, the observation window 70 may be or may be not installed. In case the jump-up detection device 74 is installed in the actual apparatus, it is possible to detect whether or not a wafer jumps up while carrying out an actual wafer processing.

The jump-up detection device 74 includes a discharge detection unit 76 for detecting at least one of a discharge current and a discharge voltage generated between the wafer W and the susceptor 34 when the wafer W is separated from the susceptor 34; and a judging unit 78 for judging an occurrence of the jump-up of the wafer W based on the detection result by the discharge detection unit 76. Further, a display unit 80 for printing or displaying the judging result is connected to the judging unit 78.

To be specific, the discharge detection unit 76 is electrically connected to the showerhead 8 and detects, herein, e.g., a discharge voltage. The lifter pins 58 start to rise in response to an instruction from, e.g., the main body control section 72 and, accordingly, the wafer W is lifted up by leading ends of the lifter pins 58 to be separated from a surface of the electrostatic chuck 36 of the susceptor 34. The moment the wafer W is separated from the surface of the electrostatic chuck 36, if a predetermined amount of residual charges exists on the wafer W, a discharge occurs between the wafer W and the susceptor 34. Further, the wafer W jumps up instantaneously due to an impact of the discharge, and the discharge detection unit 76 detects the discharge voltage at this time. The following is a reason why a discharge voltage or a discharge current generated between the wafer W and the susceptor 34 can be detected via the showerhead 8. When a charge neutralization voltage of a DC high voltage is applied to the conductor pattern 40 of the electrostatic chuck 36, a plasma is instantanesously generated in the processing vessel 4. Since the plasma remains in the processing vessel 4 for a while, it serves as a conductor and a current flows toward the showerhead 8 when a discharge occurs. Accordingly, a discharge voltage or a discharge current can be detected via the showerhead 8.

The judging unit 78 including, e.g., a micro computer or the like compares a detection voltage detected by the discharge detection unit 76 with a threshold value after the lifter pins 58 started to rise. If the detection voltage is greater than or equal to the threshold value, the judging unit 78 determines that the wafer W jumps up from the susceptor 34.

Herein, the threshold value can be variably set within a range of, e.g., from 0 V to −1000 V. For example, if the threshold value is set to be 0 V, the judging unit 78 determines that the wafer jumps up even when a slight discharge voltage is generated.

Further, the discharge detection unit 76 can be connected to the processing vessel 4 instead of being connected to the showerhead 8.

Hereinafter, a method for obtaining conditions for an optimal charge neutralization voltage by using the jump-up detection mechanism for the wafer will be described.

First of all, during a processing of a semiconductor wafer, e.g., a plasma CVD film forming process, the wafer W is mounted on the electrostatic chuck 36 of the susceptor 34. Then, a DC high voltage of, e.g., +2500 V, is applied from the positive DC power supply 44A of the high voltage DC power supply 44 to the conductor pattern 40 of the electrostatic chuck 36, and the Coulomb force generated therefrom attracts and holds the wafer W on the electrostatic chuck 36. Further, while attracting and holding the wafer W thereon, a predetermined processing gas is introduced from the showerhead 8 into the processing vessel 4. At the same time, the processing vessel 4 is evacuated so that an interior thereof can be maintained at a predetermined pressure. By applying a high frequency voltage from the high frequency power supply 18 to a portion between the showerhead 8 as the upper electrode and the susceptor 34 as the lower electrode and generating a plasma in the processing space S, a predetermined plasma process such as a film forming or the like is performed. Further, if necessary, a bias voltage is applied from the high frequency bias power supply 52 to the susceptor 34.

In case the wafer W is unloaded from the processing vessel 4 after the predetermined plasma process is completed, both high frequency power supplies 18 and 52 stop applying a high frequency voltage. At the same time, a DC positive high voltage stops being applied to the conductor pattern 40 of the electrostatic chuck 36, and the processing gas stops being supplied into the processing vessel 4. Furthermore, a gas substitution is carried out in the processing vessel 4. Next, in order to remove a large amount of residual charges existing on the wafer W attracted and held by the Coulomb force, the changeover switch 46 of the high voltage DC power supply 44 is switched into the negative DC power supply 44B. Thus, a high voltage of an opposite polarity, i.e., a DC negative high voltage that is different from that applied when the wafer is attracted and held, is applied to the conductor pattern 40 of the electrostatic chuck 36 for a predetermined period of time, e.g., about five seconds.

After the charge neutralization voltage for removing the residual charges on the wafer W is applied, the main body control section 72 outputs an instruction signal for raising the lifter pins 58 to raise the lifter pins 58. By such a manner, the wafer W is lifted up by the leading ends of the lifter pins 58 to be separated from the susceptor 34 or from the surface of the electrostatic chuck 36. At this time, if an amount of residual charge still exists on the wafer W due to an insufficient operation for removing the residual charges on the wafer W, there will develop a discharge 82 between the wafer W and the susceptor 34, as illustrated in FIG. 2. At the same time, the wafer W jumps up due to an impact of the discharge.

In such case, an observer checks whether or not the wafer W jumps up through the observation window 70 with eyes. Since, however, there exists individual difference, it is very difficult to obtain an objective judgment.

Therefore, in the present invention, a discharge voltage generated by the discharge 82 is detected by the discharge detection unit 76 of the jump-up detection device 74, and the detection value is inputted into the judging unit 78. The judging unit 78 including a microcomputer or the like compares the detection voltage with a predetermined threshold value. In case the detection voltage is greater than the threshold value, it is determined that there is the jump-up of the wafer. On the other hand, in case the detection voltage is less than or equal to the threshold value, it is determined that there is no jump-up of the wafer. Further, the display unit 80 displays the judging result.

As described above, it is possible to objectively, accurately and automatically determine whether or not the wafer W jumps up. Therefore, by judging whether or not the wafer W jumps up while varying a voltage value or applying time of the charge neutralization voltage, it is possible to accurately and quickly obtain charge neutralization conditions for preventing an occurrence of the jump-up of the wafer W.

Hereinafter, the aforementioned judging process for the occurrence of the jump-up of the wafer W will be described with reference to the flowchart illustrated in FIG. 3.

First of all, by operating the jump-up detection device 74, the discharge detection unit 76 starts to detect a discharge voltage (S1). Next, by applying a negative charge neutralization voltage to the electrostatic chuck 36 to which a DC positive high voltage has been applied, specifically, to the conductor pattern 40, for a predetermined period of time, e.g., about five seconds (S2), a manipulation for removing residual charges on the wafer W is performed.

Thereafter, if a lift-up signal for raising the lifter pins 58 is outputted from the main body control section 72 (YES in S3), the discharge detection unit 76 checks whether or not a discharge voltage is detected (S4). Here, if the discharge voltage is detected (YES in S4), the judging unit 78 checks whether or not a detection value of the detected discharge voltage is greater than a predetermined threshold value (S5). It is preferable that the threshold value is set to be variable within a range of, e.g., from 0 V to −1000 V.

Next, in case the detection value of the discharge voltage is greater than the threshold value (YES in S5), the judging unit 78 determines that the wafer jumps up (S6) and, then, the display unit 80 displays the judging result (S7).

Meanwhile, in case the discharge voltage is not detected in the S4 (NO in S4) or a detection value is less than the threshold value (NO in S5) even though the discharge voltage is detected in the S5, it is checked whether or not a predetermined period of time has passed since the output of the lift-up signal of the lifter pins 58 (S8). This is because a short period of time, e.g., about 0.5 seconds, is required until the lifter pins 58 are actually raised and start to lift up the wafer W after the lift-up signal of the lifter pins 58 is outputted. Herein, a time needed until the wafer W is completely separated from the susceptor 34 is set to be a predetermined period of time. In general, three seconds are sufficient for the period of time.

Further, the S4 and S5 are repeatedly performed until the predetermined period of time passes.

In case the discharge voltage is not detected or even though it is detected, if a state in which the detection value is less than the threshold value has lasted for a predetermined period of time (YES in S8), the judging unit 78 judges that there is no jump-up of the wafer W (S9) and, then, the display unit 80 displays the judging result (S7).

In this manner, it is possible to automatically, objectively and quickly judge whether or not the jump-up of the wafer W occurs.

Herein, it has been actually examined whether or not the wafer jumps up when the wafer is lifted up to be separated from the susceptor 34 while varying the charge neutralization voltage. The result thereof will be described with reference to FIG. 4.

As depicted in FIG. 4, the charge neutralization voltage varies from −500 V to −3000 V, and the occurrence of the jump-up of the wafer, which is observed with naked eyes, is described as reference. In the naked eye judgment of FIG. 4, X indicates a case where the occurrence of the jump-up was definitely detected by eyes; Δ indicates a case where the occurrence thereof was slightly detected by eyes; and ◯ indicates a case where the occurrence was not detected by eyes. Such naked eye judgment shows an average result obtained by performing an evaluation multiple times under same conditions. Further, “lifter pin lift-up” in FIG. 4 represents a moment when the lift-up signal of the lifter pins was outputted. Herein, a voltage of +2500 V is applied when the wafer is attracted and held, and each of the charge neutralization voltages is applied for five seconds, respectively.

As clearly can be seen from FIG. 4, in case the charge neutralization voltage is −500 V and −1000 V, a large discharge voltage was detected and a large jump-up was detected by the naked eye judgment, which is undesirable.

In the meantime, in case the charge neutralization voltage is −1500 V and −1750 V, the discharge voltage was slightly detected, and a voltage value of the discharge voltage decreases as an absolute value of the charge neutralization voltage increases. In this case, a subtle jump-up of the wafer was slightly detected by the naked eye judgment.

Further, in case the charge neutralization voltage increases and varies from −2000 V to −3000 V, the discharge voltage was not detected and the jump-up of the wafer was not detected by the naked eye judgment.

As described above, the judgment on the existence of the discharge voltage is approximately identical to the naked eye judgment result indicating the average result obtained by multiply performing the same evaluation. Accordingly, it is proved that detecting the discharge voltage can quickly and precisely detect whether or not the wafer jumps up.

In this case, it is satisfactory that the charge neutralization voltage is set to be greater than or equal to −1500 V and, preferably, greater than or equal to −2000 V. However, an excessive increase in the charge neutralization voltage causes an dielectric breakdown of devices formed on the wafer surface or the like and, thus, a maximum value thereof is a voltage value that does not induce a breakdown of the devices. For instance, since a DC current of +2500 V is applied to the electrostatic chuck when the wafer is attracted and held, it is preferable to set a maximum value of the charge neutralization voltage to be −2500 V whose absolute value is equal to the aforementioned voltage. Therefore, in graphs illustrated in FIG. 4, a proper condition of the charge neutralization voltage ranges from −1500 V to −2500 V and an optimal condition thereof is to set the voltage in the range from −2000 V to −2500 V.

At this time, if a discharge voltage value ΔV detected in case of the charge neutralization voltage being −1500 V is set to be a threshold value (absolute value) of the judging unit 78, it is possible to obtain a charge neutralization voltage for the proper condition (−1500 to −2500 V). Further, if the threshold value is set to be 0 V, a charge neutralization voltage of the optimal condition (−2000 to −2500 V) can be obtained. In this case, it is preferable that the threshold value ranges from 0 to −1000 V when the discharge voltage is detected.

In the graphs of FIG. 4, a discharge voltage is shown before the lifter pins are raised. The discharge voltage is generated due to large residual charges on the wafer W when the charge neutralization voltage is applied to the electrostatic chuck 36. Such discharge voltage is irrelevant to the jump-up of the wafer and, thus, can be ignored.

Further, herein, the discharge detection unit 76 detects a discharge voltage, but is not limited thereto. A discharge current showing the same pattern of the discharge voltage may also be detected, or both of the discharge voltage and the discharge current may be detected to thereby improve an accuracy of detecting the occurrence of the jump-up. The threshold value preferably ranges 0 to 10 mA when the discharge current is detected.

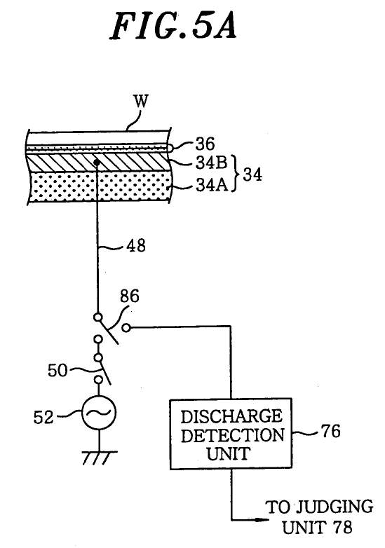

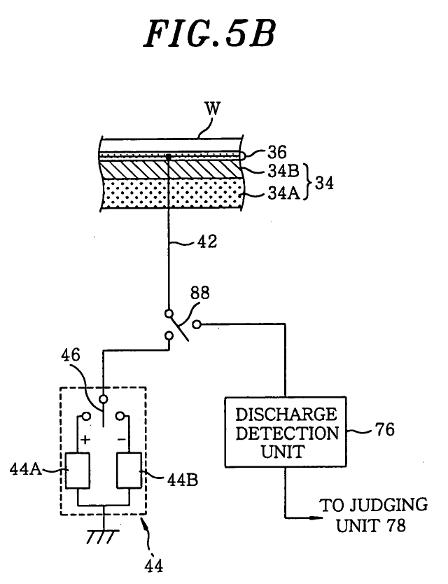

Although a case where the discharge detection unit 76 is connected to the showerhead 8 has been described, but the connecting position is not limited thereto and any position will do as long as the discharge voltage or the discharge current can be detected. For example, it can be installed as illustrated in FIGS. 5A and 5B.

FIGS. 5A and 5B depict exemplary modifications of a connection type of the discharge detection section. As illustrated in FIG. 5A, a first changeover switch 86 can be interposed at a lead line 48 connecting a high frequency bias power supply 52 and the conductor base 34B of the susceptor 34 and, further, the discharge detection unit 76 can be connected to the first changeover switch 86. Besides, the first changeover switch 86 can be switched into the discharge detection unit 76 right before the wafer W is lifted up by the lifter pins 58 (see FIG. 1).

As shown in FIG. 5B, a second changeover switch 88 can be interposed at a lead line 42 connecting the high voltage DC power supply 44 and the conductor pattern 40 of the electrostatic chuck 36 and, further, the discharge detection unit 76 can be connected to the second changeover switch 88. In addition, the second changeover switch 88 can be switched into the discharge detection unit 76 right before the wafer W is lifted up by the lifter pins 58 (see FIG. 1).

Furthermore, in case of an apparatus in which an upper electrode is not installed, the discharge detection unit 76 can be connected to the processing vessel 4.

Although a plasma CVD apparatus has been described as an example in the above-described embodiments, the present invention can be applied to other plasma processing apparatuses, e.g., a plasma etching apparatus.

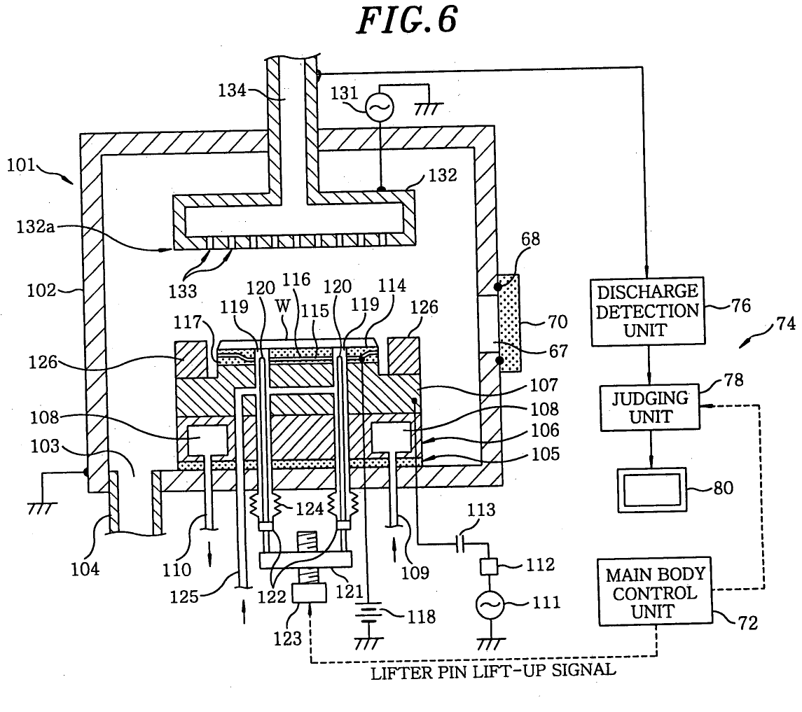

FIG. 6 presents a state in which a jump-up detection mechanism for a wafer is installed at a plasma etching apparatus. Detailed explanations of parts identical to those described in FIG. 1 will be omitted, and like reference numerals will be used therefor.

A plasma etching apparatus 101 has an electrically grounded and air-tightly sealed processing vessel 102 made of aluminum or the like.

A gas exhaust port 103 installed at a bottom portion of the processing vessel 102 is connected to a gas exhaust line 104 leading into a gas exhaust unit (not shown) such as a vacuum pump or the like. Due to the gas exhaust unit, an interior of the processing vessel 102 is uniformly evacuated through a peripheral bottom portion thereof, thereby maintaining a predetermined depressurized atmosphere, e.g., a predetermined value ranging from a few mTorr to several tens Torr.

A susceptor support member 106 is installed at a central bottom portion of the processing vessel 102 via an insulating plate 105, e.g., ceramic or the like. Further, installed on a top surface of the susceptor support member 106 is a susceptor 107 serving as a lower electrode and made of aluminum or the like.

A cooling chamber 108 is formed in the susceptor support member 106. A cooling coolant, which is introduced from a coolant introducing line 109 provided at a bottom portion of the processing vessel 102 and discharged through a coolant discharge line 110, is circulated in the cooling chamber 108.

A high frequency power ranging from 100 to 2500 W at a frequency of 13.56 MHz is supplied from a high frequency power supply 111 installed at an outside of the processing vessel 102 to the susceptor 107 via a matching circuit 112 and a blocking capacitor 113.

Furthermore, installed on a top surface of the susceptor 107 is an electrostatic chuck 114 on which a semiconductor wafer W is directly mounted to be attracted and held. The electrostatic chuck 114 is configured such that a conductive layer 115 made of, e.g., copper electric field foil, is interposed and adhered between insulators 116 and 117 such as ceramic, polyimide film or the like.

Moreover, when a DC voltage ranging, e.g., from 1000 V to 3000 V, is applied from a high voltage DC power supply 118 installed at the outside of the processing vessel 102 to the conductive layer 115, the semiconductor wafer W is attracted and held on a top surface of the electrostatic chuck 114, i.e., a surface of the insulator 116, by the Coulomb force.

Formed at the electrostatic chuck 114, the susceptor 107, the susceptor support member 106, the insulating plate 105 and a bottom portion of the processing vessel 102 are a plurality of heat conduction medium channels 119 vertically penetrating therethrough. Lifter pins 120 for vertically moving the semiconductor wafer W are penetrably inserted into the heat conduction medium channels 119.

Each lower portion of the lifter pins 120 is fixedly attached to one of support portions 122 of a vertically moving plate 121 at the outside of the processing vessel 102. The vertically moving plate 121 is vertically movable by a driving unit 123, e.g., a pulse motor or the like. Accordingly, if the vertically moving plate 121 vertically moves by operating the driving unit 123, each of the lifter pins 120 moves up and down, and each top surface of the lifter pins 120 is projected from a surface of the upper insulator 116 of the electrostatic chuck 114 or sunk in the heat conduction medium channels 119. Further, as for the driving unit 123, an air cylinder 62 shown in FIG. 1 or the like can be used.

When the top surfaces of the lifter pins 120 are projected from the surface of the upper insulator 116 of the electrostatic chuck 114, the semiconductor wafer W is positioned on a corresponding top surface or unloaded from the corresponding top surface.

Further, bellows 124 are installed between each of the support portions 122 of the vertically moving plate 121 and an outer bottom surface of the processing vessel 102. The heat conduction medium channels 119 serving as respective vertically moving paths of the lifter pins 120 are air-tightly sealed against the atmosphere by the bellows 124.

The heat conduction medium channels 119 lead to a gas supply line 125 introduced from the outside of the processing vessel 102 via the insulating plate 105, the susceptor support member 106 and the susceptor 107. In case a He gas, for example, flows into the gas supply line 125 by a separately installed gas supply system (not shown), a cold heat is thermally conducted to the corresponding He gas via the susceptor support member 106 and the susceptor 107. Then, the He gas cooled in such manner reaches a surface of the insulator 116 of the electrostatic chuck 114 via the heat conduction medium channels 119. As a result, it is possible to control the semiconductor wafer W mounted on the surface of the corresponding insulator 116 at a predetermined temperature, e.g., a random temperature ranging from 150° C. to −50° C.

Further, a ring-shaped focus ring 126 made of an insulator is installed on a top surface of the susceptor 107 to surround the electrostatic chuck 114, wherein a height of the focus ring 126 is set to be approximately equal to that of the semiconductor wafer W mounted on the electrostatic chuck 114. Due to the presence of such focus ring 126, reactive ions generated in the processing vessel 102 by a production of a plasma are effectively irradiated on the wafer W.

Meanwhile, an upper electrode 132 is installed in an upper portion in the processing vessel 102, the upper electrode 132 being connected to a high frequency power supply 131 generating a high frequency power of, e.g., 60 MHz for a plasma excitation. The entire upper electrode 132 has a hollow structure, and a surface 132a facing the electrostatic chuck 114 is made of, e.g., quartz. Further, a plurality of gas diffusion holes 133 is installed on the facing surface 132a, and a processing gas supplied from the gas inlet opening 134 installed at a central upper portion of the upper electrode 132 is uniformly discharged through the gas diffusion holes 133 to the semiconductor wafer W mounted on the electrostatic chuck 114. In other words, the upper electrode 132 is configured as a showerhead portion.

Further, as described in FIG. 1, the observation opening 67 is formed at the sidewall of the processing vessel 102, and the observation window 70 made of, e.g., quartz, is air-tightly attached to the observation opening 67 by the sealing members 68 such as an O-ring or the like. Furthermore, an entire operation of the apparatus 101 is controlled by a main body control section 140 including, e.g., a microcomputer or the like.

Installed at the plasma etching apparatus 101 configured as described above is the jump-up detection device 74 including the discharge detection unit 76, the judging unit 78 and the display unit 80, which are identical to those illustrated in FIG. 1. Such apparatus can provide the same effects as those of the exemplary apparatus described in FIG. 1 and automatically detect whether or not a wafer jumps up when the wafer is lifted up to be separated from the susceptor by the lifter pins.

Although the plasma processing apparatus has been described as an example in the aforementioned embodiments, the present invention is not limited thereto and, further, can be applied to any processing apparatus in which an electrostatic chuck is installed, e.g., an exposure apparatus or the like.

Moreover, even though the semiconductor wafer has been described as an example of a wafer in these embodiments, the present invention is not limited thereto and, further, can be applied in a processing of an LCD substrate, a glass substrate or the like.

As described above, in accordance with the present invention, following distinguished effects can be provided.

When the wafer is lifted up to be separated from the susceptor by the lifter pins, if the wafer jumps up, a slight discharge is generated between the wafer and the susceptor. The discharge detection section detects a discharge voltage or a discharge current generated in such case, and the judging section judges an occurrence of the jump-up. Accordingly, it is possible to detect the occurrence of the jump-up of the wafer automatically, accurately, objectively and quickly. Therefore, an optimal value for a charge neutralization voltage can be easily obtained.

While the invention has been shown and described with respect to the preferred embodiments, it will be understood by those skilled in the art that various changes and modifications may be made without departing from the spirit and scope of the invention as defined in the following claims.

1. A processing apparatus comprising:
a processing vessel;
a susceptor installed in the processing vessel and having an electrostatic chuck for attracting and holding an object to be processed;
lifter pins, elevatably installed with respect to the susceptor, for separating the object from the susceptor; and
a jump-up detection device for detecting whether or not the object jumps up from the susceptor when the object is lifted up to be separated therefrom by the lifter pins,
wherein the jump-up detection device includes:
a discharge detection unit for detecting at least one of a discharge current and a discharge voltage generated between the object and the susceptor when the object is separated from the susceptor; and
a judging unit for judging whether or not the object jumps up based on a detection result of the discharge detection unit.

2. The processing apparatus of claim 1, further comprising a display unit for displaying a judging result of the judging section.

3. The processing apparatus of claim 1, wherein a showerhead serving as an upper electrode and for discharging a processing gas into the processing vessel is installed at a ceiling portion of the processing vessel and the discharge detection unit is connected to the showerhead to thereby detect at least one of the discharge current and the discharge voltage.

4. The processing apparatus of claim 1, wherein an upper electrode and a lower electrode to which a high frequency voltage for generating a plasma is applied are installed in the processing vessel, and the discharge detection unit is connected to the upper electrode to thereby detect at least one of the discharge current and the discharge voltage.

5. The processing apparatus of claim 1, wherein the discharge detection unit is connected to the processing vessel to thereby detect at least one of the discharge current and the discharge voltage.

6. The processing apparatus of claim 1, wherein the judging unit has a threshold value.

7. The processing apparatus of claim 6, wherein the threshold value ranges from about 0 to about −1000 V when the discharge voltage is detected.

8. The processing apparatus of claim 6, wherein the threshold value ranges from 0 to about 10 mA when the discharge current is detected.

9. The processing apparatus of claim 1, wherein the susceptor has an electrically conductive base connected to a high frequency power supply and the conductive base is switchably connected to the discharge detection unit.

10. The processing apparatus of claim 1, wherein the electrostatic chuck of the susceptor is connected to a high voltage power supply, and the electrostatic chuck is switchably connected to the discharge detection unit.

11. The processing apparatus of claim 1, wherein the processing apparatus is a plasma processing apparatus.

12. The processing apparatus of claim 1, wherein the processing apparatus is an exposure apparatus.

13. A processing method for use with a processing apparatus having a processing vessel, a susceptor installed in the processing vessel and including an electrostatic chuck, and lifter pins, the processing method comprising the steps of:
(a) attracting and holding an object to be processed on the susceptor in the processing vessel by a Coulomb force of the electrostatic chuck;
(b) separating the object from the susceptor by lifting it up by the lifter pins after applying a charge neutralization voltage to the electrostatic chuck; and
(c) detecting whether or not the object jumps up from the susceptor when the object is lifted up by the lifter pins,
wherein the detecting step (c) further includes the steps of:
(c1) detecting at least one of a discharge current and a discharge voltage generated between the object and the susceptor when the object is separated from the susceptor; and
(c2) judging whether or not the object jumps up based on a detection result of the step (c1).

14. The processing method of claim 13, wherein a jump-up of the object is detected when the object is separated from the susceptor after performing a plasma processing on the object.
